(19) United States
(12) Patent Application Publication
(10) Pub. No.: US 2021/0349867 A1
(43) Pub. Date: Nov. 11, 2021

(54) SYSTEM AND METHODS FOR RECEIVING, PROCESSING AND STORING RICH TIME SERIES DATA

(71) Applicant: Worthy Technology LLC, Austin, TX (US)

(72) Inventors: Ryan Faber, Westport, CT (US); Robert Maciej Pieta, Glenview, IL (US); David Samuel Raphael, Brooklyn, NY (US)

(73) Assignee: Worthy Technology LLC, Austin, TX (US)

(21) Appl. No.: 17/308,021

(22) Filed: May 4, 2021

Related U.S. Application Data
(60) Provisional application No. 63/022,024, filed on May 8, 2020.

(51) Int. Cl. G06F 16/215; G06F 16/11; H03M 7/30; G06F 16/23; G06F 16/2455

(52) U.S. Cl. CPC G06F 16/215; G06F 16/116; G06F 16/24564; G06F 16/2322; H03M 7/30

(57) ABSTRACT

Provided for is a system for processing rich time-series data. Such a system may comprise an Application Programming Interface (API) subsystem, the API subsystem providing an interface for a third-party data source to transmit data. The system may further include a data receiver subsystem, the data receiver subsystem configured to verify the incoming data, said verification comprising authenticating whether the incoming data is rich time-series data. Further, the system may include a data processor subsystem, a database subsystem configured to store data, and a monitoring subsystem configured to transmit one or more alerts.

### CLAIM OF PRIORITY

This application claims priority from U.S. Provisional Patent Application No. 63/022,024, filed on May 8, 2020, the contents of which are incorporated herein by reference.

### FIELD OF THE INVENTION

This disclosure relates to a system and methods for processing and storing data. Specifically, this disclosure relates to a system and methods for receiving, processing, and storing rich time series data.

### BACKGROUND

Current technologies capture an ever-increasing amount of data. Indeed, current hardware needs worldwide are increasing, as all types of data captured grows exponentially.

The growth of personalized software and recommendation engines can be attributed to increased data access. As technology is ever-present, data is constantly generated in increasing magnitude. Not only is the sheer amount of data expanding, but the number and types of devices and systems generating and recording such data has expanded. For example, hardware devices, mobile applications, webpages, servers, cloud systems, sensors, switches, and routers all generate significant data.

Various forms of data may be used. For example, time-series data, which is data shown, utilized, or otherwise indexed as a series of points over time. Thus, specific data may be associated with a point in time. Time-series data is often important for viewing and analyzing patterns over time, forecasting future results or events, and analyzing whether other patterns exist.

A subset of time series data, rich time-series data, often provides the visual and forecasting advantages of time-series data, but with additional datapoints. That is, rich time-series data contains a data object identifier, as well as a time stamp.

Rich time-series data is critical for software systems, and for large-scale data processing and analysis. Indeed, as an enhanced form of time-series data, rich time-series data provides essential datapoints for measuring changes over time, predicting all sorts of future events, whether it be weather, financial markets, pandemics, health, self-driving vehicles, retail, crime and safety, defense, and a host of other industries.

Rich time-series data is both captured, and then utilized. While solutions exist to capture rich time-series data effectively, many do not adequately provide for retrieving such rich time-series data in a performance-oriented manner. Moreover, current solutions are not effective at monitoring data transmissions for possible non-compliant data, such that non-compliant time-series data may mistakenly be incorporated into rich time-series data sets.

It would be desirable, therefore, to provide systems and methods for easily and effectively capturing rich time-series data. It would be further desirable, therefore, to provide systems and methods for enhancing retrieval parameters associated with rich time-series data.

It would be yet further desirable to provide systems and methods for validating and properly capturing rich time series data and ensuring that all data captured and processed is rich time-series data.

### SUMMARY OF THE INVENTION

The invention of the present disclosure may be a system for processing rich time-series data. Such a system may comprise an Application Programming Interface (API) subsystem, the API subsystem providing an interface for a third-party data source to transmit data. The system may further include a data receiver subsystem, the data receiver subsystem configured to verify the incoming data, said verification comprising authenticating whether the incoming data is rich time-series data. Further, the system may include a data processor subsystem, a database subsystem configured to store data, and a monitoring subsystem configured to transmit one or more alerts.

In other embodiments of the system, the data is JSON-encoded object data, XML-encoded object data, query parameter encoded object data, or byte-encoded object data. The data may be transmitted via a TCP/IP protocol, FTP, or other protocol for data transmission. The data processor subsystem may be configured to scrub data by removing unwanted data attributes and/or to add data by inserting new data attributes. The data processor subsystem may also be configured to normalize data. The normalization may be selected from a group consisting of mathematical, statistical, or rule-based normalization. Moreover, the data processor subsystem may be configured to compress data using one or more compression techniques. In an embodiment, the data processor subsystem may be configured to create one or more rows in a database subsystem. The one or more rows may be configured to store scrubbed, normalized and compressed data. The data processor may be configured to remove one or more specified keys. The database row key may be formed of a fixed length and a structured format. Further, the structure format may be formed of one or more subkeys of fixed lengths separated by a character.

In an embodiment, each row is associated with a database row key. In an embodiment, the monitoring subsystem may transmit alerts using electronic means. The incoming data may be comprised of a plurality of datapoints, each of the plurality of datapoints comprising at least one data object identifier. Each of the plurality of datapoints may further comprise a timestamp. The timestamp may be representative of a time at which the datapoint occurred, was received, transmitted, or generated. In an embodiment, the alert or alerts may be triggered by a pre-determined event and/or rule.

### BRIEF DESCRIPTION OF THE DRAWINGS

FIG. 1 is an illustrative block diagram of system based on a computer.

FIG. 2 is an illustration of a computing machine.

FIG. 3 is an illustration of a method and process for receiving, processing, and storing rich time-series data.

### DETAILED DESCRIPTION OF THE INVENTION

The detailed description provided herein, along with accompanying figures, illustrates one or more embodiments, but is not intended to describe all possible embodiments. The detailed description provides exemplary systems and methods of technologies, but is not meant to be limiting, and similar or equivalent technologies, systems, and/or methods may be realized according to other examples as well.

Those skilled in the art will realize that storage devices utilized to provide computer-readable and computer-executable instructions and data can be distributed over a network. For example, a remote computer or storage device may store computer-readable and computer-executable instructions in the form of software applications and data. A local computer may access the remote computer or storage device via the network and download part or all of a software application or data and may execute any computer-executable instructions. Alternatively, the local computer may download pieces of the software or data as needed, or process the software in a distributive manner by executing some of the instructions at the local computer and some at remote computers and/or devices.

Those skilled in the art will also realize that, by utilizing conventional techniques, all or portions of the software's computer-executable instructions may be carried out by a dedicated electronic circuit such as a digital signal processor (“DSP”), programmable logic array (“PLA”), discrete circuits, and the like. The term “electronic apparatus” may include computing devices or consumer electronic devices comprising any software, firmware or the like, or electronic devices or circuits comprising no software, firmware or the like.

The term “firmware” as used herein typically includes and refers to executable instructions, code, data, applications, programs, program modules, or the like maintained in an electronic device such as a ROM. The term “software” as used herein typically includes and refers to computer-executable instructions, code, data, applications, programs, program modules, firmware, and the like maintained in or on any form or type of computer-readable media that is configured for storing computer-executable instructions or the like in a manner that may be accessible to a computing device.

The terms “computer-readable medium”, “computer-readable media”, and the like as used herein and in the claims are limited to referring strictly to one or more statutory apparatus, article of manufacture, or the like that is not a signal or carrier wave per se. Thus, computer-readable media, as the term is used herein, is intended to be and must be interpreted as statutory subject matter.

The term “computing device” as used herein and in the claims is limited to referring strictly to one or more statutory apparatus, article of manufacture, or the like that is not a signal or carrier wave per se, such as computing device 101 that encompasses client devices, mobile devices, wearable devices, one or more servers, network services such as an Internet services or corporate network services based on one or more computers, and the like, and/or any combination thereof. Thus, a computing device, as the term is used herein, is also intended to be and must be interpreted as statutory subject matter.

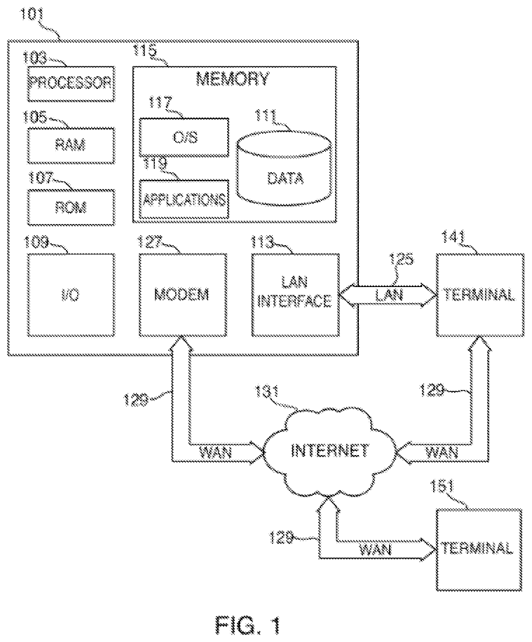

FIG. 1 is an illustrative block diagram of system 100 based on a computer 101. The computer 101 may have a processor 103 for controlling the operation of the device and its associated components, and may include RAM 105, ROM 107, input/output module 109, and a memory 115. The processor 103 will also execute all software running on the computer—e.g., the operating system. Other components commonly used for computers such as EEPROM or Flash memory or any other suitable components may also be part of the computer 101.

The memory 115 may be comprised of any suitable permanent storage technology—e.g., a hard drive. The memory 115 stores software including the operating system 117 any application(s) 119 along with any data 111 needed for the operation of the system 100. Alternatively, some or all of computer executable instructions may be embodied in hardware or firmware (not shown). The computer 101 executes the instructions embodied by the software to perform various functions.

Input/output (“I/O”) module may include connectivity to a microphone, keyboard, touch screen, and/or stylus through which a user of computer 101 may provide input, and may also include one or more speakers for providing audio output and a video display device for providing textual, audiovisual and/or graphical output.

System 100 may be connected to other systems via a LAN interface 113.

System 100 may operate in a networked environment supporting connections to one or more remote computers, such as terminals 141 and 151. Terminals 141 and 151 may be personal computers or servers that include many or all of the elements described above relative to system 100. The network connections depicted in FIG. 1 include a local area network (LAN) 125 and a wide area network (WAN) 129, but may also include other networks. When used in a LAN networking environment, computer 101 is connected to LAN 125 through a LAN interface or adapter 113. When used in a WAN networking environment, computer 101 may include a modem 127 or other means for establishing communications over WAN 129, such as Internet 131.

It will be appreciated that the network connections shown are illustrative and other means of establishing a communications link between the computers may be used. The existence of any of various well-known protocols such as TCP/IP, Ethernet, FTP, HTTP and the like is presumed, and the system can be operated in a client-server configuration to permit a user to retrieve web pages from a web-based server. Any of various conventional web browsers can be used to display and manipulate data on web pages.

Additionally, application program(s) 119, which may be used by computer 101, may include computer executable instructions for invoking user functionality related to communication, such as email, Short Message Service (SMS), and voice input and speech recognition applications.

Computer 101 and/or terminals 141 or 151 may also be devices including various other components, such as a battery, speaker, and antennas (not shown).

Terminal 151 and/or terminal 141 may be portable devices such as a laptop, cell phone, smartphone, smartwatch, or any other suitable device for storing, transmitting and/or transporting relevant information. Terminals 151 and/or terminal 141 may be other devices. These devices may be identical to system 100 or different. The differences may be related to hardware components and/or software components.

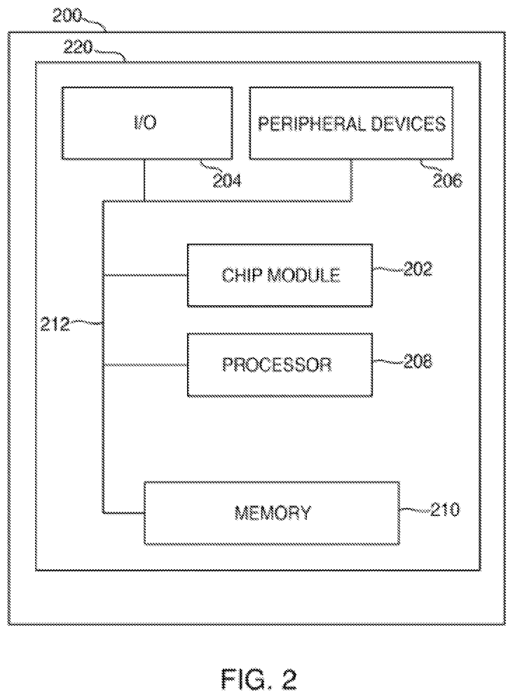

FIG. 2 shows illustrative apparatus 200. Apparatus 200 may be a computing machine. Apparatus 200 may include one or more features of the apparatus shown in FIG. 1. Apparatus 200 may include chip module 202, which may include one or more integrated circuits, and which may include logic configured to perform any other suitable logical operations.

Apparatus 200 may include one or more of the following components: I/O circuitry 204, which may include a transmitter device and a receiver device and may interface with fiber optic cable, coaxial cable, telephone lines, wireless devices, PHY layer hardware, a keypad/display control device or any other suitable encoded media or devices; peripheral devices 206, which may include counter timers, real-time timers, power-on reset generators or any other suitable peripheral devices; logical processing device 208, which may test submitted information for validity, scrape relevant information, aggregate user financial data and/or provide an auth-determination score(s) and machine-readable memory 210.

Machine-readable memory 210 may be configured to store in machine-readable data structures: information pertaining to a user, information pertaining to an account holder and the accounts which he may hold, the current time, information pertaining to historical user account activity and/or any other suitable information or data structures.

Components 202, 204, 206, 208 and 210 may be coupled together by a system bus or other interconnections 212 and may be present on one or more circuit boards such as 220. In some embodiments, the components may be integrated into a single chip. The chip may be silicon-based.

Disclosed herein are systems, apparatuses, and methods (“the system”) for receiving, processing and/or storing rich time-series data.

In one embodiment, the system monitors incoming data streams and analyzes the data points. The system then classifies the data as rich time series data. In another embodiment, the system may classify the data as non-rich time series data, and transmit the data to memory. In a further embodiment, the system may further categorize the non-rich time series data after transmission to memory. In another embodiment, the rich time series data and/or the non-rich time series data may be analyzed more than once (for example, to account for error if there is a likelihood of error).

In an embodiment, the system may transmit alerts when non-rich time-series data is inadvertently stored or transmitted as rich time-series data.

In accordance with an embodiment, rich time-series data may be comprised of a series of datapoints. Each datapoint may contain at least one data object identifier and a timestamp. The data object identifier may be a value, such as any suitable value. The value may be a unique value that corresponds to the rich time-series datapoint. As a non-limiting example, “123-123” may be a data object identifier. In an embodiment, the data object identifier may be randomly generated. In such an embodiment, the processor or another component of the computing device may be configured to randomize a string for the data object identifier. As a non-limiting example, the data object identifier is often a randomly generated string like “1335bb54”.

The data object identifier may be associated with a plurality of datapoints. For example, the data object identifier may be associated with three datapoints that are related to one another. However, in alternate embodiments, the data object identifier may be associated with any number of datapoints.

In an embodiment, multiple data object identifiers may be used to determine a representative data object identifier. As a non-limiting example, a new randomly generated string like “34e983b6” may be assigned as a representative data object identifier to uniquely identify a datapoint with multiple data object identifiers.

In an embodiment, multiple data object identifiers may be assigned to a new data object identifier.

The timestamp may be in any suitable format. For example, ISO 8601 format may be used, which may be displayed as “2020-04-22T01:45:35+00:00.” Alternatively, any other suitable timestamp format may be utilized. The timestamp may correspond to the time at which the rich time-series datapoint occurred, is received, transmitted, generated, or otherwise processed. In another embodiment, there may be more than one timestamps where each timestamp correlates to either the time at which the rich time-series datapoint occurred, is received, transmitted, generated, or otherwise processed.

In certain embodiments, a rich time-series datapoint will contain or be associated with additional data. The additional data may be formatted in any suitable way, and may be in addition to the data object identifier and timestamp. Moreover, the additional data may be specifically bundled with, or correspond to, the data object identifier and/or timestamp. As a non-limiting example, a key “platform” and associated value “web” may be used to indicate that the rich time-series datapoint occurred on a web platform.

In an embodiment, the system may receive, process, generate and/or store time series data. The system may include an application programming interface (API). The API may include an API subsystem. The API subsystem may allow a data source to access data. The API subsystem may allow a third-party data source to send the data. In one example, the third-party data source may send JavaScript Object Notation (“JSON”)-encoded object data. In an embodiment, the object data may be encoded as XML-encoded object data, query parameter encoded object data, or byte-encoded object data.

The data may be transmitted via a suitable protocol, such as TCP/IP, to an HTTP endpoint, or an HTTPS endpoint. The data may be sent to the HTTPS endpoint if protected by secure sockets layer (“SSL”) and transport layer security (“TLS”). In an embodiment, the data may be transmitted with or without request authentication, such as a secret token or OAuth key.

The system may include a data receiver. The data receiver may be a data receiver subsystem. The data receiver may verify incoming data. The data receiver may verify that the incoming data is rich time-series data (in doing so, the data receiver may also indicate incoming data that is non-rich time-series data).

The system may include a data processor. The data processor may be a data processor subsystem. The data processor may be configured to cleanse or scrub data. In one embodiment, the data processor may be specifically configured to remove certain types of data, or certain attributes, or certain values. As a non-limiting example, the data processor may remove values associated with the key “email”. In another example, the data processor may replace data matching the format ###-##-#### inside of any string in incoming data with a new string “X”. In another embodiment, the data processor may be configured to remove all data deemed improper.

In an embodiment, the data may be scrubbed by removing unwanted, erroneous or improper data attributes, keys, values or other artifacts. For example, the data processor may remove all data keys or attributes with a value of NULL, “ ”, and/or an undefined value. In an embodiment, the data processor may be configured to remove one or more specified keys, such as keys containing the string “email.”

The data processor may be further configured to normalize data, using any suitable method. Data normalization may correspond to eliminating data units of measurement, for data comparison. Thus, the data processor may be associated with a database. This allows for data redundancy elimination, reduction of errors, and improvement of data integrity. For example, the data may be normalized using z-score normalization on numerical values, t-score, feature scaling, standardizing residuals, normalizing moments, normalizing vectors to a norm of one, or any other suitable process.

The data processor may compress the data. The data may be compressed using one or more compression techniques. For example, algorithms or code may be used, such as Base64 encoding, GZip compression, or any other suitable methods.

The data processor may create, within a database subsystem, a new storage location. In one embodiment, a plurality of rows may be created for scrubbed, normalized and compressed data. Each row may be associated with a database row key. In an embodiment, the database row key may be a performance-optimized database row key.

The database row key may be an identifier for each row. The value of the database row key is unique, with the database row key being an internal database identifier for the row. The database row key may be formed of a fixed length and structured format. The structured format may be formed of one or more subkeys of fixed lengths, separated by a character (such as, for example, but not limited to “#,” “%,” “&” or any other suitable character), or an empty string “ ”.

The system may further include a database subsystem. The database subsystem may be configured to store data. The data may be stored in a Structured Query Language (“SQL”), non-SQL (“NOSQL”), or any other format. The data may be encrypted or not encrypted. In an embodiment, some segments of data may be encrypted, while other segments of data are not encrypted. The database subsystem may provide for stored data to be queried and/or sequentially read.

The system may yet further include a monitoring subsystem. The monitoring subsystem may be configured to transmit one or more alerts. The alerts may be in any suitable form, such as an electronic alert via SMS, email, vibration, telephone call, or instant message. The alerts may be triggered by a predetermined event or rule. In one embodiment, the predetermined event or rule may be receipt of a message or error from a system component. In one example, the predetermined event or rule may be improper processing of non-rich time-series data. In an embodiment, the alerts may be stored, creating a history of alerts. In an embodiment, the invention of the present disclosure is, or is in communication with, a system or apparatus including a speaker, a monitor display, a vibrating motor, an indicator, and/or other signaling component.

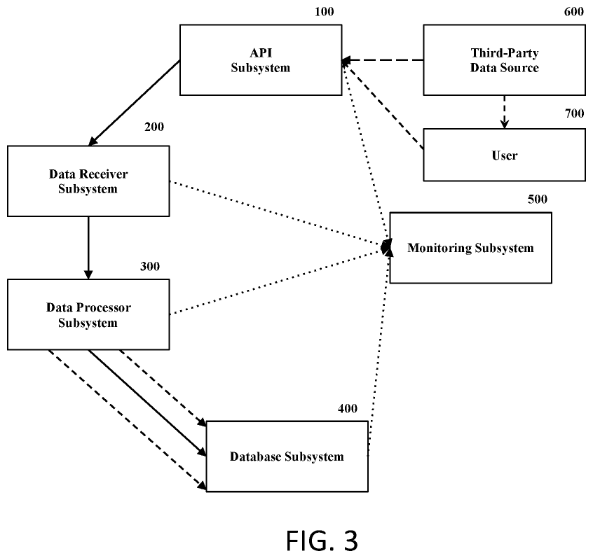

FIG. 3 illustrates an exemplary method and process for receiving, processing, and storing rich time-series data.

A third-party data source, such as third-party data source 600, may be associated with rich time-series data. The third-party data source 600 may be any suitable data source, such as a social media platform, search engine, or any other data-rich environment. The third-party data source 600 transmits a rich time-series datapoint to an API subsystem, such as API subsystem 100. The third-party data source 600 may transmit a JSON-encoded rich time-series datapoint to an API subsystem 100 REST endpoint ‘/data/collect’, using TCP/IP protocols, and protected by SSL/TLS with an ‘Authorization’ request header set to ‘source_123.’

In one embodiment, the API subsystem 100 may validate one or more processes. In an embodiment, the API subsystem 100 may validate whether incoming data from third-party data sources 600 is encoded with the expected data encoding, such as JSON. In a further embodiment, the API subsystem 100 may validate whether third-party data sources 600 are properly authenticated. Properly authenticated sources may be configured to submit, or retrieve from, data to API subsystem 100, using, for example, an “Authorization” header with a secret token. In an embodiment, unauthenticated sources may trigger an alert.

In accordance with an embodiment, if the API subsystem 100 determines that an incoming data request is invalid, the API subsystem 100 may notify the monitoring subsystem 500. In one example, the notification may include a string message such as “request invalid, data source is unauthenticated.” Alternatively, the notification may be a time-out or error message.

In accordance with some embodiments, rich time-series data need not necessarily enter API subsystem 100 directly from third-party data source 600. For example, authenticated User 700 may upload one or more rich time-series datapoints, from a third-party data source 600, in a JSON formatted file. The datapoints may be uploaded in a JSON formatted file to an API Subsystem 100 REST endpoint ‘/data/upload’ using TCP/IP protected by SSL/TLS with a ‘Authorization’ request header set to ‘user_123’. In an embodiment, rich time-series data enters API subsystem 100 from both the user 700 and the third-party data source 600.

The API subsystem 100 may accept one or more rich time-series datapoints for each request. In one embodiment, a plurality of rich time-series datapoints may be encoded in a JSON list.

In certain embodiments, data deemed valid by API subsystem 100 is then transmitted to data receiver subsystem 200. In addition to transmitting the valid data, API subsystem 100 may transmit the identity of the third-party data source 600 contributing the incoming data.

In an embodiment, data receiver subsystem 200 may verify the incoming data. That is, subsystem 200 may verify that the incoming data is authentic rich time-series data. The subsystem 200 may validate incoming JSON-encoded data for authenticity of rich time-series by implementing the following:

```
function validate parameter (data: string):
  obj := parse string as JSON
  if obj.invalid raise exception “Invalid encoding”
  identifier := obj get key “id” if exists otherwise NULL
  timestamp := obj get key “time” if exists otherwise NULL
  if identifier = = NULL raise exception “Invalid object identifier”
  if timestamp = = NULL raise exception “Invalid timestamp”
  return identifier, timestamp
```

In an embodiment, subsystem 200 may validate incoming data for authenticity by implementing a function for validating a single string argument data. In such an embodiment, first, data is parsed as JSON into an object, otherwise an “Invalid encoding” exception is raised. Further, the “id” key and “time” key may be extracted from the object. In an embodiment, if either does not exist, an exception is raised. This function may then return the values associated with the “id” key and “time” key of the parsed object.

Data receiver subsystem 200 may be implemented to validate one or more additional validation criteria. For example, subsystem 200 may further require JSON-encoded data to contain the key “platform.”

Data receiver subsystem 200 may validate incoming data from distinct third-party data sources 600, using different methods. For example, the data receiver subsystem 200 may ensure incoming data contains at least a specific set of keys. In another example, the data receiver subsystem 200 may extract values from incoming data based on the source:

```
if request.Authorization is data source 1:
  get timestamp using key “time”
otherwise if request.Authorization is. data source 2:
  get timestamp using key “iso8601”
```

In the event that subsystem 200 does not classify incoming data as rich time-series data, and/or determines that the incoming data is indeed non-rich time-series data, data receiver subsystem 200 may notify the monitoring subsystem 500 of such a determination. An exemplary notification may be a string message such as “Data invalid, missing identifier,” or any other suitable message, a time-out, or an error message. In another embodiment, the notification may be a string message configured to output information regarding one or more additional validation criteria.

In the event that subsystem 200 classifies the data as rich time-series data, the data is then transmitted onward to data processor subsystem 300. The data receiver subsystem 200 may further transmit to the subsystem 300 the identity of which third-party data source 600 transmitted the incoming data. In an embodiment, the data processor subsystem 300 may be configured to accept only some data or portions of data (for example, the data processor subsystem 300 may receive the data as rich time-series data, but not the identity of which third-party data source 600 transmitted the incoming data).

The data processor subsystem 300 may process and store data in the database subsystem 400. The data processor subsystem 300 may alter data prior to storage in the database subsystem 400. For example, the data processor subsystem 300 may add a timestamp to the data. Another example, the data processor subsystem 300 may remove information in the data that matches a format like ###-##-####. However, the data processor subsystem 300 may remove information in the data that matches, is similar to, or is opposite any data or data format. Rich time-series data stored in the database subsystem 400 may include a database row key or a performance-optimized database row key. The database row key or performance-optimized database row key may include a plurality of subkeys.

The subkeys may originate as variable length strings. In an embodiment, the subkeys are set to a fixed length. The fixed length may be predetermined. Thus, subkeys shorter than the desired fixed length are padded with a character, such as “_”, and subkeys longer than the desired fixed length are split and hashed. The split and hash thereby preserve the readability of the subkey, while ensuring the subkey has a fixed length. This may allow the database row key to be performance optimized.

In one embodiment, the database row key or performance-optimized database row key function may be implemented as follows:

```
function format (parameter value: String, parameter n: Int):
  if value.length < n.
    padding = “ ” * (n − value, length)
    return value + padding
  else if value.length = = n:
    return value
  else:
    prefix := the first n-10 characters of value
    postfix := the last 10 characters of the base64 sha256 of value
    return prefix + postfix
function createKey (parameter: components [String]) :
  components := map format for each component in components
  key := components joined with “_”
  return key
```

In accordance with an embodiment, an exemplary data processor subsystem 300 may be implemented as:

```
function process (parameter data: Data):
  data := data removing all keys with values NULL
  data := data removing all keys in [“email”, “phone”]
  data[“score”] = data[“raw_score”] / 100.0
  compressedData := gzip(base64(jsonString(data)))
  keyComponents1 := [data[“identifier”], data[“timestamp”]]
  databaseKey := createKey(keyComponents1)
  Database.Table1.save(compressedData, databaseKey)
  keyComponents2 := [data[“timestamp”], data[“identifier”]]
  databaseKey2 := createKey(keyComponents2)
  Database.Table2.save(compressedData, databaseKey2)
```

In an embodiment, an exemplary data processor subsystem 300 may be implemented as a function to process data, with a single data argument. In an embodiment, first, all NULL values are removed from the passed in data. Next, the key “email” and key “phone,” and associated values if such values exist, may be removed from the passed in data. In an embodiment, additionally, a key “score” is set by taking the value of the key “raw_score” in the passed in data and dividing by 100.0. In such an embodiment, this function then computes the gzip compressed form of the base64 encoded string of the JSON string representation of the passed in data. In an embodiment, this function computes two database row keys using the values for the key “identifier” and key “timestamp” in the passed in data, and saves the compressed form of the data to Table1 and Table2 in the database.

Data processor subsystem 300 may create one or more rows in the database subsystem 400 for each stream of incoming data processed. The rows may be associated with the same row key, or may have different row keys, and be stored in one or more tables of one or more databases.

While this invention has been described in conjunction with the embodiments outlined above, many alternatives, modifications and variations will be apparent to those skilled in the art upon reading the foregoing disclosure. Accordingly, the embodiments of the invention, as set forth above, are intended to be illustrative, not limiting. Various changes may be made without departing from the spirit and scope of the invention.

What is claimed is:

1. A system for processing rich time-series data, comprising:
an Application Programming Interface (API) subsystem, the API subsystem providing an interface for a third-party data source to transmit data;
a data receiver subsystem, the data receiver subsystem configured to verify incoming data, said verification comprising authenticating whether the incoming data is rich time-series data;
a data processor subsystem;
a database subsystem configured to store data; and
a monitoring subsystem configured to transmit one or more alerts.

2. The system of claim 1, wherein the data is JSON-encoded object data, XML-encoded object data, query parameter encoded object data, or byte-encoded object data.

3. The system of claim 1, wherein the data is transmitted via a TCP/IP protocol, FTP, or other protocol for data transmission.

4. The system of claim 1, wherein the data processor subsystem is configured to scrub data by removing unwanted data attributes.

5. The system of claim 1, wherein the data processor subsystem is configured to add data by inserting new data attributes.

6. The system of claim 1, wherein the data processor subsystem is configured to normalize data.

7. The system of claim 6, wherein the data is normalized using normalization selected from a group consisting of mathematical, statistical, or rule-based normalization.

8. The system of claim 1, wherein the data processor subsystem is configured to compress data using one or more compression techniques.

9. The system of claim 1, wherein the data processor subsystem is configured to create one or more rows in the database subsystem.

10. The system of claim 9, wherein the one or more rows are configured to store scrubbed, normalized and compressed data.

11. The system of claim 10, wherein each row is associated with a database row key.

12. The system of claim 1, wherein the monitoring subsystem transmits alerts using electronic means.

13. The system of claim 1, wherein the incoming data is comprised of a plurality of datapoints, each of the plurality of datapoints comprising at least one data object identifier.

14. The system of claim 13, wherein each of the plurality of datapoints further comprises a timestamp.

15. The system of claim 14, wherein the timestamp is representative of a time at which the datapoint occurred, was received, transmitted, or generated.

16. The system of claim 4, wherein the data processor is configured to remove one or more specified keys.

17. The system of claim 11, wherein the database row key is formed of a fixed length and a structured format.

18. The system of claim 17, wherein the structure format is formed of one or more subkeys of fixed lengths separated by a character.

19. The system of claim 12, wherein the alert is triggered by a predetermined rule.
